(19) United States
(12) Patent Application Publication
(10) Pub. No.: US 2006/0055435 A1
(43) Pub. Date: Mar. 16, 2006

(54) Dynamic slice level detector

(75) Inventor: Roeland John Heijna, Nijmegen (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V.````, BA Eindhoven (NL)

(21) Appl. No.: 10/531,396

(22) PCT Filed: Sep. 19, 2003
(86) PCT No.: PCT/IB03/04207

§ 371 Date: Apr. 14, 2005

(30) Foreign Application Priority Data
Oct. 17, 2002 (EP) 02079304.8

(51) Int. Cl. H03K 5/22

(52) U.S. Cl. 327/65

(57) ABSTRACT

A detector (1) for detecting a differential binary signal (Vin), having a first signal level during a first period and a second signal level during a second period, the detector (1) comprises an offset circuit (5) for producing a slice level offset signal in response to the detected binary signal (Vout), an amplitude signal (Vcon) and a slice level signal. The differential binary signal is detected using a first slice level during the first period and using a second slice level during the second period.

The present invention relates to a dynamic slice level detector. More in particular, the present invention relates to a detector for detecting a binary signal, provided with circuits for dynamically adjusting the slice level.

The two signal levels of a binary signal are usually referred to as “high” and “low” and may represent a logical “1” and “0” respectively. The “high” level may correspond to a signal level of, for example, +5V while the “low” level may correspond to a signal level of, for example, −5V or ground i.e. 0 V. When recovering a transmitted binary signal, it has to be decided which signal portions are high and which are low. To this end, a threshold level is usually set approximately halfway between the high and the low signal levels. Any signal level exceeding this threshold or “slice level” is considered to represent a high level, otherwise the signals are categorized as low.

In the presence of noise it is possible that errors are introduced. Noise peaks present in the low level signal portions may exceed the slice level so as to incorrectly cause a high level to be detected, and vice versa.

U.S. Pat. No. 4,707,740 discloses a sync detector for recovering a sync signal from a video signal. A slice level signal is adjusted during a low level (“sync tip”) portion of the video signal. To this end, a noise detector provides an output representative of the average noise during this low level signal portion. This noise detector output is used to generate a positive slice level offset during the low level signal portions and a negative offset of the same magnitude during the high level signal portions. As a consequence, the slice level offset during the high level signal portions is not based on the actual noise or signal level in those portions but on an estimated level. This may give rise to detection errors. In addition, this Prior Art arrangement is not suitable for differential signal processing.

Accordingly, the present invention provides a detector for detecting a differential binary signal having a first signal level during a first period and a second signal level during a second period, the detector comprising:

an amplitude detection circuit for producing an amplitude signal indicative of the amplitude of both the first and the second period of the binary signal,

a slice level detection circuit for producing a slice level signal indicative of the average slice level to be applied to the binary signal,

an output circuit for outputting the detected binary signal,

an offset circuit for producing a slice level offset signal in response to the outputted binary signal, the slice level signal and the amplitude signal, and

a level shift circuit coupled to the output circuit for level shifting the binary signal in response to the slice level offset signal,

wherein said circuits are coupled so as to detect the differential binary signal using a first slice level during the first period and using a second slice level during the second period, and wherein all said circuits are differential circuits.

By using the amplitude signal of both the first and the second signal levels, a slice level offset signal is produced, which reflects the actual signal and noise levels in both levels and thus more accurately determines the offset of the slice level. This in turn decreases the number of detection errors.

By using differential circuits, such as a differential slice level detection circuit, a differential amplitude detection circuit, a differential output circuit, a differential offset circuit and a differential level shift circuit, it is possible to process differential signals all the way down.

Advantageously, the detector of the present invention may further comprise a first additional level shift circuit coupled to the amplitude detection circuit and/or a second additional level shift circuit coupled to the slice level detection circuit.

Preferably, the detector further comprises a decoupling circuit for decoupling the binary signal prior to feeding it to the other circuits. Such a decoupling circuit may consist of a single capacitor connected in series to each input terminal.

The present invention also provides an offset circuit for use in a detector as defined above, the offset circuit comprising:

a first differential amplifier for processing the detected differential binary signal, and

at least a second differential amplifier for processing the slice level signal and its inverse.

Further differential amplifiers or non-differential amplifiers may be present in the offset circuit. To allow a rapid change of signal levels it is preferred that the amplifiers comprise bipolar NPN-transistors.

The present invention will further be explained below with reference to exemplary embodiments illustrated in the accompanying drawings, in which:

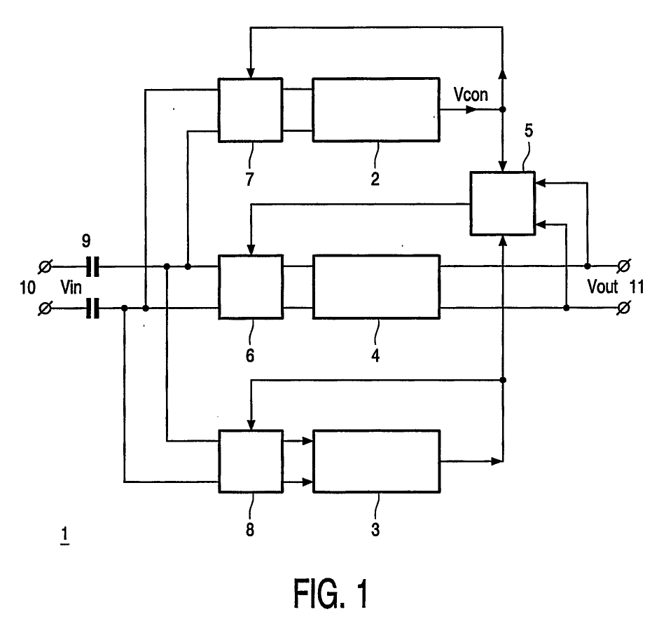

FIG. 1 schematically shows a block diagram of the detector of the present invention.

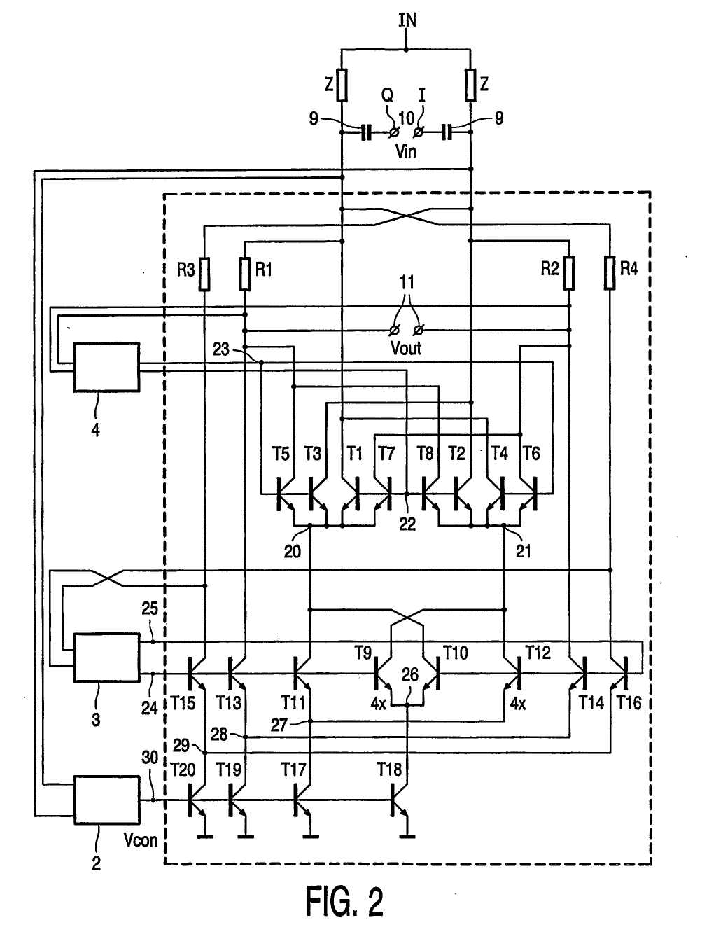

FIG. 2 schematically shows a preferred embodiment of the detector of the present invention.

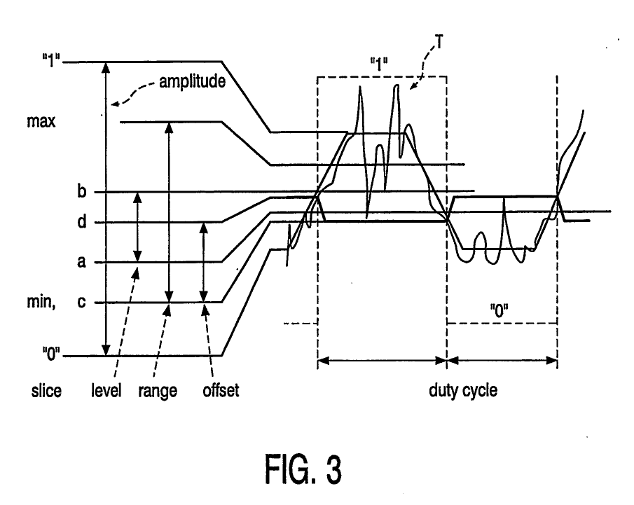

FIG. 3 schematically shows examples of various signal levels in the detector of FIG. 1.

The detector 1 shown merely by way of non-limiting example in FIG. 1 comprises input terminals 10 for receiving the binary signal Vin having mutually in anti-phase components I and Q. First, second and third level shift circuits 6, 7 and 8 are connected to the input terminals 10 via decoupling capacitors 9. The outputs of the first, second and third level shift circuits 6, 7 and 8 are connected to an amplitude detection circuit 2 for producing an amplitude signal indicative of the amplitude of the binary signal, a slice level detection circuit 3 for producing a slice level signal indicative of the average slice level to be applied to the binary signal, and an output circuit 4 coupled to output terminals 11 for outputting the detected binary signal, respectively. The output circuit 4 is in the embodiment shown constituted by a limiter circuit.

In accordance with the present invention an offset circuit 5 is provided for producing a slice level offset signal in response to the detected binary signal, the amplitude signal and the slice level signal. To this end, the outputs of the amplitude detection circuit 2 and the slice level circuit 3 are coupled to the offset circuit 5, as are the outputs of the output circuit (limiter) 4. This allows the offset circuit 5 to produce a slice level offset signal which takes the detected binary signal into account and which may therefore vary in accordance with the signal period: the slice level is preferably lowered when the signal level is high and raised when the signal level is low. This is effected by level shift circuit 6 which level shifts the binary signal in response to the slice level offset signal and thus offsets the slice level relative to the signal level.

In the embodiment of FIG. 2, all said circuits 2, 3, 4, 5, 6 are implemented as differential circuits, that is, they are capable of processing a differential signal. The resistors R1-R4, in conjunction with the associated transistors T1-T20 which control the currents through these resistors R1-R4, constitute the level shift circuits 6, 7 and 8, encircled by broken lines. As can be seen, transistors T1-T8 and T9-T16 constituting first and second differential amplifiers are used for this purpose.

The NPN bipolar transistors T1-T8 form the level shift circuit 6 (FIG. 1), constituting first differential amplifiers. The emitters of the transistors T1, T3, T5 and T7 are connected to a first emitter connection point 20. Likewise, the emitters of the transistors T2, T4, T6 and T8 are connected to a second emitter connection point 21. The bases of the transistors T1, T2, T7 and T8 are connected to each other and form a first base connection point 22. The bases of the transistors T3, T4, T5 and T6 are connected to each other and form a second base connection point 23. The collector of transistor T1 is coupled to the collector of transistor T4 and, by a decoupling capacitor 9, to the input terminal Q of the circuit. The collector of transistor T2 is connected to the collector of transistor T3 and, by a decoupling capacitor 9, to the input terminal I of the circuit. The collector of transistor T5 is connected to the collector of transistor T8 and to a first end of the resistor R1, a second end of which being connected to the collectors of the transistors T1 and T4. The collectors of the transistors T6 and T7 are connected to an end of the second resistor R2, another end of which being connected to the collectors of the transistors T2 and T3.

The bipolar transistors T9-T16 implement a level shift circuit 8 (FIG. 1), constituting second differential amplifier. The transistors T9 and T12 are arranged such that their emitter current is substantially 4 times larger than the emitter current of any one of the transistors T10, T11, T13, T14 and T15.

The bases of the transistors T9, T11, T13 and T15 are connected to a third base connection point 24. The bases of the transistors T10, T12, T14 and T16 are connected to a fourth base connection point 25. The emitters of the transistors T9 and T10 are connected to a third emitter connection point 26. The emitters of the transistors T11 and T12 are connected to a fourth emitter connection point 27. The emitters of the transistors T13 and T14 are connected to a fifth emitter connection point 28 and the emitters of the transistors T15 and T16 are connected to a sixth emitter connection point 29. The collectors of the transistors T9 and T12 are coupled to the second emitter connection point 21 and the collectors of the transistors T10 and T11 are coupled to the first emitter connection point 20. The collector of transistor T13 is connected to resistor R1 at the end thereof to which the collectors of the transistors T5 and T8 are connected. The collector of transistor T14 is connected to resistor R2 at the end thereof to which the transistors T6 and T7 with their collectors are connected.

The collector of transistor T15 is connected to an end of a resistor R3, another end of which connects, via the decoupling capacitor 9, to the input terminal I. The collector of transistor T16 is connected to an end of a resistor R4, another end of which connects, via its associated decoupling capacitor 9, to the input terminal Q.

The bipolar NPN transistors T17-T20 form the level shift circuit 7 of FIG. 1. The emitters of the transistors T17-T20 are connected to signal ground, indicated by a short horizontal line, and the bases of the transistors T17-T20 are connected to a fifth base connection point 30. The collector of transistor T7 is connected to the fourth emitter connection point 27. The collector of the transistor T18 is connected to the third emitter connection point 26. The collector of the transistor T19 is connected to the fifth emitter connection point 28 and the collector of the transistor T20 is connected to the sixth emitter connection point 29. The output of the amplitude detection circuit 2 is coupled to the fifth base connection point 30. The input of the amplitude detection circuit 2 is coupled to the input terminals I, Q, via the respective decoupling capacitors 9.

The inputs of the slice level detection circuit 3 connect to the collectors of the transistors T15 and T16, respectively, and the outputs of the slice level detection circuit 3 is connected to the third 24 and fourth base connection point 25, respectively.

The outputs of the output circuit 4 is coupled to the first 22 and second base connection point 23, respectively. The outputs of the output circuit 4 is coupled to the resistors R1 and R2, respectively, at the ends thereof which connect to the collectors of the transistors T4, T6, T14 and the collectors of the transistors T3, T5, T8 and T13, respectively.

The output signal of the output circuit 4 at the output terminals 11 is indicated as Vout, as it is shown in FIG. 2.

As shown in FIG. 2, the amplitude signal Vcon outputted by the amplitude detection circuit 2, controls the overall currents through the detector circuit via the transistors T17-T20, while the slice level signal (in conjunction with its inverse), outputted by the slice level detection circuit 3, adjusts the level shift through the transistors T9-T16. The detected signal output of the output circuit or limiter 4 causes a final level shift equivalent to the slice level offset by the transistors T1-T8.

The current input I of the level shift circuit is coupled to 50 impedance Z. The input signal Vin is differential with a common mode level which is set by the amplitude detection circuit 2. By this common mode level all parameters relative to the input amplitude are set. That is, the differential input currents Ie and If are set such that:
Ie=If=(Ia+Ib+Ic+Id)/2
wherein:

Ia, Ib, Ic and Id are the collector currents of transistors T20, T19, T17 and T18, respectively.

If the currents Ia, Ib, Ic and Id are equal, each having a value I, then the current through the 50Ω impedances, i.e. resistors in the preferred embodiment, each are substantially 2*I.

The resistors R1-R4 are chosen to be equal having a value R. The relation between the 50Ω impedance Z and the value R determines the maximum slice level.

By the 4:1 and 1:4 relation of the currents in the second differential amplifiers, (i.e. the relation of the emitter currents and emitter substrate surfaces) a static offset can be provided. This will further be explained with reference to FIG. 3.

The binary signal T shown in FIG. 3 has two signal level, a high signal level (which may represent a logical “1”) during a first period and a low signal level (which may represent a logical “0”) during a second period. Both signal levels are corrupted by noise. In the example shown, the noise level during the first period is greater than the noise level during the second period. This is, however, not essential to the present invention. The slice level should be chosen such that a high level is detected during the first period and a low level is detected during the second period. As can be seen, the basic or average slice level a is set lower than the zero signal level b. In addition, the slice level is set lower during the first period (decision “1” in the present example) and higher in the second period (decision “0” in the present example) so as to result in offset slice levels c and d respectively. Minimum and maximum values are set for these offset slice levels. In the example shown in FIG. 3, the minimum value min coincides with the offset slice level c of the first period, while the maximum level max exceeds the offset slice level d of the second period. If the offset is zero, the basic slice level a results.

The detector of the present invention is particularly suitable for use in transimpedance amplifiers and limiters in optical links.

It will be understood by those skilled in the art that the present invention is not limited to the embodiments illustrated above and that many modifications and additions may be made without departing from the scope of the invention as defined in the appending claims.

1. A detector for detecting a differential binary signal having a first signal level during a first period and a second signal level during a second period, the detector comprising:
an amplitude detection circuit for producing an amplitude signal indicative of the amplitude of both the first and the second period of the binary signal,
a slice level detection circuit for producing a slice level signal indicative of the average slice level to be applied to the binary signal,
an output circuit for outputting the detected binary signal,
an offset circuit for producing a slice level offset signal in response to the outputted binary signal, the slice level signal and the amplitude signal, and
a level shift circuit coupled to the output circuit for level shifting the binary signal in response to the slice level offset signal,
wherein said circuits are coupled so as to detect the differential binary signal using a first slice level during the first period and using a second slice level during the second period, and wherein all said circuits are differential circuits.

2. A detector according to claim 1, wherein the output circuit comprises a limiter circuit.

3. A detector according to claim 1, further comprising a first additional level shift circuit coupled to the amplitude detection circuit and/or a second additional level shift circuit coupled to the slice level detection circuit.

4. A detector according to claim 1, further comprising a decoupling circuit for decoupling the binary signal prior to feeding it to the other circuits.

5. An offset circuit for use in a detector according to claim 1, the offset circuit comprising:
a first differential amplifier for processing the detected differential binary signal, and
at least a second differential amplifier for processing the slice level signal and its inverse.

6. An offset circuit according to claim 5, wherein the slice level offset signal is limited to a maximum and a minimum value.
